(19) United States
(12) Patent Application Publication
(10) Pub. No.: US 2020/0373339 A1
(43) Pub. Date: Nov. 26, 2020

(54) IMAGE SENSOR

(71) Applicant: LG INNOTEK CO., LTD., Seoul (KR)

(72) Inventor: Ssang Soo LEE, Seoul (KR)

(73) Assignee: LG INNOTEK CO., LTD., Seoul (KR)

(21) Appl. No.: 16/960,526

(22) PCT Filed: Jan. 7, 2019
(86) PCT No.: PCT/KR2019/000211

§ 371 Date: Jul. 7, 2020

(30) Foreign Application Priority Data
Jan. 8, 2018 (KR) 10-2018-0002217

(51) Int. Cl. H01L 27/146

(52) U.S. Cl. CPC H01L 27/14605

(57) ABSTRACT

An image sensor according to an embodiment includes a plurality of pixel zones disposed adjacent to each other, wherein the plurality of pixel zones comprise: a central pixel zone; and a peripheral pixel zone disposed around the central pixel zone, wherein the central pixel zone comprises a plurality of central pixels, wherein the peripheral pixel zone comprises a plurality of peripheral pixels, wherein sizes of the central pixels are smaller than sizes of the peripheral pixels.

### TECHNICAL FIELD

Embodiments relate to an image sensor.

### BACKGROUND ART

Image sensors (or color sensors or optical sensors) that convert light into electrical signals according to the intensity thereof and output the electrical signals are widely known. Image sensors are mainly used for devices that adjust illuminance or require on/off control in accordance with the living environment of human beings.

Image sensors are used in display devices in order to detect the ambient luminance of the display devices and to adjust the display brightness thereof. That is, the display brightness of display devices is appropriately adjusted in accordance with the ambient luminance detected by image sensors, with the result that the visibility of display devices may be improved, and thus unnecessary consumption of electric power may be reduced. For example, image sensors used to adjust brightness may be applied to display devices such as mobile phones or computers having displays.

An image sensor includes a photoelectric conversion element, such as a photodiode, in order to sense light. That is, the image sensor is capable of detecting illuminance based on the amount of current flowing through the photoelectric conversion element. To this end, the image sensor includes color filters for filtering light in a specific wavelength band and photodiodes disposed corresponding to respective color filters. Examples of color filters include a green color filter that transmits green (G) light, a red color filter that transmits red (R) light, and a blue color filter that transmits blue (B) light. The photodiodes sense light transmitted from the respective color filters, generate electrical signals having levels corresponding to the intensities of the sensed light, and output the generated electrical signals.

FIG. 1 illustrates a plan view of a conventional image sensor.

Referring to FIG. 1, a conventional image sensor includes color pixels R, G and B that provide color image information. Because the sizes of the plurality of pixels included in the conventional image sensor are the same, the resolution throughout the center portion and peripheral portion of the image sensor is uniform. However, research is being conducted on image sensors that take into consideration the characteristics of human vision.

### DISCLOSURE

### Technical Problem

Embodiments provide an image sensor designed taking into consideration the characteristics of human vision so as to exhibit improved resolution.

The objects to be accomplished by the disclosure are not limited to the above-mentioned objects, and other objects not mentioned herein will be clearly understood by those skilled in the art from the following description.

### Technical Solution

An image sensor according to an embodiment may include a plurality of pixel zones disposed adjacent to each other. The plurality of pixel zones may include a central pixel zone and a peripheral pixel zone disposed around the central pixel zone. The central pixel zone may include a plurality of central pixels, and the peripheral pixel zone may include a plurality of peripheral pixels. The sizes of the central pixels may be smaller than the sizes of the peripheral pixels.

For example, when viewed in plan, the central pixel zone may be a zone from the center of the image sensor to a first point, and the first point may be a point falling within 3/10 to 7/10 of the total distance from the center to the edge of the image sensor.

For example, the central pixel zone and the peripheral pixel zone may have a concentric circular planar shape.

For example, the central pixel zone and the peripheral pixel zone may have a polygonal planar shape.

For example, the peripheral pixel zone may have a shape of a plane surrounding the central pixel zone.

For example, the peripheral pixel zone and the central pixel zone may have different planar shapes from each other.

For example, the difference between a first luminance level of the central pixels and a second luminance level of the peripheral pixels may be as follows.

ΔL=|L1−L2|<Δ1

Here, L1 represents the first luminance level, L2 represents the second luminance level, ΔL represents a luminance level difference between L1 and L2, and Δ1 represents a difference between the first luminance level and the second luminance level when the sizes of the central pixels and the sizes of the peripheral pixels are identical.

For example, the luminance level of pixels located at the boundary between the central pixel zone and the peripheral pixel zone may have an intermediate value of the first luminance level of the central pixels and the second luminance level of the peripheral pixels.

For example, the luminance level of pixels located at the boundary between the central pixel zone and the peripheral pixel zone may have an average value of the first luminance level of the central pixels and the second luminance level of the peripheral pixels.

For example, when viewed in plan, the central pixel zone may be determined as a point at which the second luminance level of the peripheral pixels is 80% or more of the first luminance level of the central pixels.

For example, the plurality of pixel zones may include a first pixel zone including pixels having a first size, the first pixel zone falling within the central pixel zone, a second pixel zone including pixels having a second size larger than the first size, the second pixel zone having a shape of a plane surrounding the first pixel zone, a third pixel zone including pixels having a third size larger than the second size, the third pixel zone having a shape of a plane surrounding the second pixel zone, and a fourth pixel zone including pixels having a fourth size larger than the third size, the fourth pixel zone having a shape of a plane surrounding the third pixel zone and falling within the peripheral pixel zone. At least one of the second pixel zone or the third pixel zone may fall within the central pixel zone or the peripheral pixel zone.

For example, the first to fourth sizes may have a relationship of multiples of 2 therebetween.

An image sensor according to another embodiment may include a plurality of pixel zones disposed so as to be adjacent to each other and to be distinguished from each other in a direction from a center to an edge. Each of the plurality of pixel zones may include a plurality of pixels. The sizes of the pixels included in the plurality of pixel zones may gradually increase from the center to the edge.

For example, the plurality of pixel zones may include a first pixel zone including pixels having a first size, a second pixel zone including pixels having a second size larger than the first size, the second pixel zone having a shape of a plane surrounding the first pixel zone, a third pixel zone including pixels having a third size larger than the second size, the third pixel zone having a shape of a plane surrounding the second pixel zone, and a fourth pixel zone including pixels having a fourth size larger than the third size, the fourth pixel zone having a shape of a plane surrounding the third pixel zone.

### Advantageous Effects

In an image sensor according to an embodiment, the sizes of pixels located in the center are smaller than the sizes of pixels located in a peripheral portion around the center so as to be suitable for the characteristics of human vision, thereby exhibiting an improved effective resolution. A process of reducing the luminance levels of pixels located in the center is not required, thereby simplifying the structure and reducing manufacturing costs compared with the conventional art. Since the luminance levels of pixels located at the boundary between a plurality of pixel zones are interpolated, natural images may be provided.

However, the effects achievable through the disclosure are not limited to the above-mentioned effects, and other effects not mentioned herein will be clearly understood by those skilled in the art from the following description.

### DESCRIPTION OF DRAWINGS

FIG. 1 illustrates a plan view of a conventional image sensor.

FIG. 2 illustrates a plan view of an image sensor according to an embodiment.

FIG. 3 illustrates a plan view of an image sensor according to another embodiment.

FIG. 4 illustrates a plan view of an image sensor according to still another embodiment.

FIG. 5 illustrates a plan view of an image sensor according to still another embodiment.

FIGS. 6A to 6D illustrate plan views of respective first to fourth pixel zones included in the image sensors illustrated in FIGS. 2 to 4.

### BEST MODE

Hereinafter, exemplary embodiments of the present disclosure will be described in detail with reference to the accompanying drawings.

The technical spirit of the disclosure is not limited to the embodiments to be described, and may be implemented in various other forms, and one or more of the components may be selectively combined and substituted for use without exceeding the scope of the technical spirit of the disclosure.

In addition, terms (including technical and scientific terms) used in the embodiments of the disclosure, unless specifically defined and described explicitly, are to be interpreted as having meanings that may be generally understood by those having ordinary skill in the art to which the disclosure pertains, and meanings of terms that are commonly used, such as terms defined in a dictionary, should be interpreted in consideration of the context of the relevant technology.

Further, the terms used in the embodiments of the disclosure are for explaining the embodiments and are not intended to limit the disclosure. In this specification, the singular forms may also include plural forms unless otherwise specifically stated in a phrase, and in the case in which “at least one (or one or more) of A, B, or C” is stated, it may include one or more of all possible combinations of A, B, and C.

In describing the components of the embodiments of the disclosure, terms such as “first”, “second”, “A”, “B”, “(a)”, and “(b)” can be used. Such terms are only for distinguishing one component from another component, and do not determine the nature, sequence or procedure etc. of the corresponding constituent elements.

In addition, when it is described that a component is “connected”, “coupled” or “joined” to another component, the description may include not only being directly “connected”, “coupled” or “joined” to the other component but also being “connected”, “coupled” or “joined” by another component between the component and the other component.

In addition, in the case of being described as being formed or disposed “above (on)” or “below (under)” another component, the description includes not only the case where the two components are in direct contact with each other, but also the case where one or more other components are formed or disposed between the two components. In addition, when expressed as “above (on)” or “below (under)”, it may refer to a downward direction as well as an upward direction with respect to one element.

Hereinafter, image sensors 100A to 100D according to embodiments will be described using the Cartesian coordinate system, but the embodiments are not limited thereto. That is, in the Cartesian coordinate system, the x-axis, the y-axis and the z-axis are perpendicular to one another, but the embodiments are not limited thereto. That is, the x-axis, the y-axis, and the z-axis may be obliquely oriented relative to one another, rather than being perpendicular to one another.

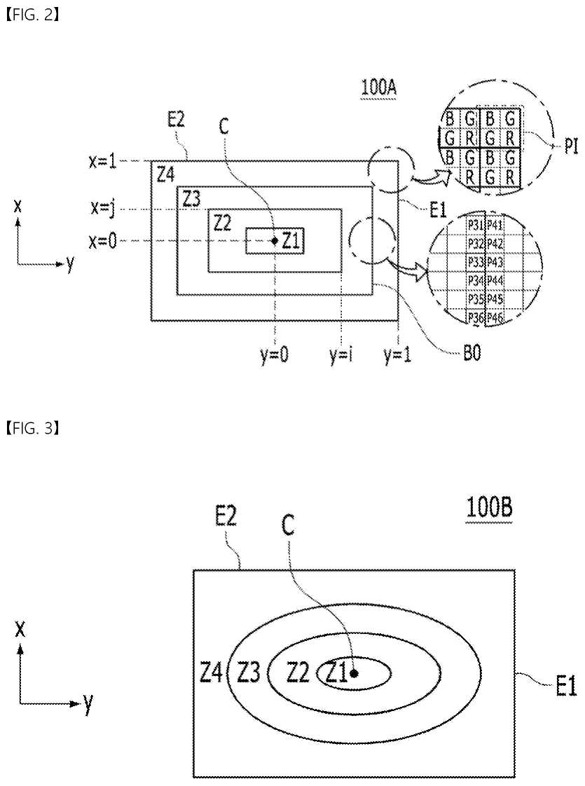

FIG. 2 illustrates a plan view of an image sensor 100A according to an embodiment.

An image sensor 100A includes a photoelectric conversion element, such as a photodiode, in order to sense light. That is, the image sensor 100A is capable of detecting illuminance based on the amount of current flowing through the photoelectric conversion element. To this end, the image sensor 100A includes color filters for filtering light in a specific wavelength band and photodiodes disposed to correspond to the respective color filters. Examples of color filters include a green color filter that transmits green (G) light, a red color filter that transmits red (R) light, and a blue color filter that transmits blue (B) light. The photodiodes sense light transmitted from the respective color filters, generate electrical signals having levels corresponding to the intensities of the sensed light, and output the generated electrical signals.

The image sensor 100A according to an embodiment may include “N” pixel zones Z disposed adjacent to each other. Here, N is a positive integer of 2 or more. For example, as illustrated in FIG. 2, the image sensor may include four (N=4) first to fourth pixel zones Z1 to Z4, but the embodiment is not limited thereto.

The plurality of pixel zones (e.g. Z1 to Z4) may include a central pixel zone and a peripheral pixel zone.

Hereinafter, the central pixel zone may be defined as a zone disposed in the center portion of each of the image sensors 100A to 100D, and the peripheral pixel zone may be defined as a zone disposed around the central pixel zone.

Further, the peripheral pixel zone may have the shape of a plane that is disposed around the central pixel zone so as to surround the central pixel zone. For example, the second pixel zone Z2 may have the shape of a plane that surrounds the first pixel zone Z1, the third pixel zone Z3 may have the shape of a plane that surrounds the second pixel zone Z2, and the fourth pixel zone Z4 may have the shape of a plane that surrounds the third pixel zone Z3.

When viewed in plan, the central pixel zone may be a zone from the center C of the image sensor 100A to a first point. Here, the first point may be a point that falls within 3/10 to 7/10 of the total distance from the center C of the image sensor 100A to the edge thereof, and, for example, may be a point corresponding to 5/10 of the total distance.

For example, referring to FIG. 2, the first point may refer to a 1-1^{st} point (y=i) and a 1-2^{nd} point (x=j). The 1-1^{st} point (y=i) may be a point corresponding to i/10 of the total distance (y=1) from the center C of the image sensor 100A to the right edge E1 (or the left edge) of the image sensor 100A in a horizontal direction (e.g. the y-axis direction). Here, i may be 3 to 7, for example, 5. The 1-2^{nd} point (x=j) may be a point corresponding to j/10 of the total distance (x=1) from the center C of the image sensor 100A to the upper edge E2 (or the lower edge) of the image sensor 100A in a vertical direction (e.g. the x-axis direction). Here, j may be 3 to 7, for example, 5. Here, i may be the same as or different from j.

The first pixel zone Z1 may fall within the central pixel zone, and the fourth pixel zone Z4 may fall within the peripheral pixel zone.

In addition, at least one of the second pixel zone Z2 or the third pixel zone Z3 may fall within the central pixel zone or the peripheral pixel zone.

For example, as illustrated in FIG. 2, the second pixel zone Z2 may fall within the central pixel zone, and the third pixel zone Z3 may fall within the peripheral pixel zone. Alternatively, unlike the illustration in FIG. 2, both the second and third pixel zones Z2 and Z3 may fall within the central pixel zone, or may fall within the peripheral pixel zone.

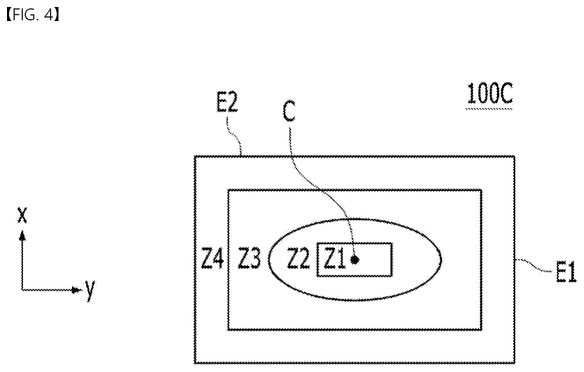

Hereinafter, a description of parts in FIGS. 3 to 6D that are the same as those in FIG. 2 will be omitted, and differences therebetween will be described.

FIG. 3 illustrates a plan view of an image sensor 100B according to another embodiment.

The central pixel zone and the peripheral pixel zone may have a polygonal planar shape, may have a circular or elliptical planar shape, or may have a planar shape that is a combination of a polygonal planar shape and a circular or elliptical planar shape. However, the embodiment is not limited as to the specific planar shape of each of the central pixel zone and the peripheral pixel zone.

For example, each of the central pixel zone and the peripheral pixel zone may have a rectangular planar shape, as illustrated in FIG. 2, or may have an elliptical planar shape, as illustrated in FIG. 3. For example, when each of the central pixel zone and the peripheral pixel zone has an elliptical or circular planar shape, the central pixel zone and the peripheral pixel zone may have a concentric circular planar shape.

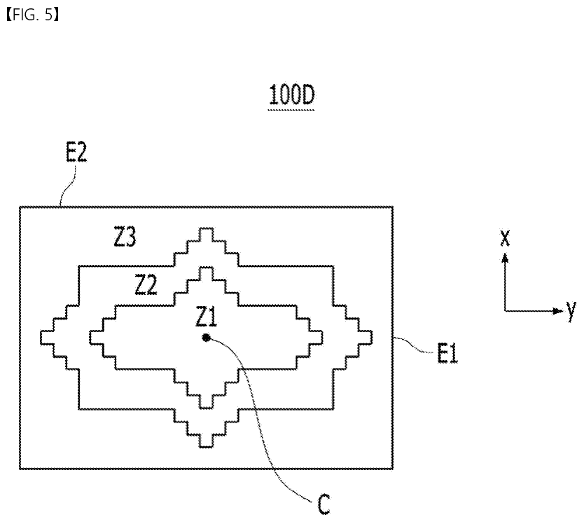

FIG. 4 illustrates a plan view of an image sensor 100C according to still another embodiment.

Alternatively, the peripheral pixel zone and the central pixel zone may have planar shapes that are different from or the same as each other. For example, the peripheral pixel zone and the central pixel zone may have the same planar shape as each other, as illustrated in FIG. 2 or 3, or may have different planar shapes from each other, as illustrated in FIG. 4.

FIG. 5 illustrates a plan view of an image sensor 100D according to still another embodiment.

Alternatively, unlike the image sensors 100A to 100C illustrated in FIGS. 2 to 4, referring to FIG. 5, the central pixel zone may be defined so as to include a greater number of pixels located in the center portion than the number of pixels located in the peripheral portion when viewed in plan.

Further, in the image sensors 100A to 100D according to the embodiments described above, the central pixel zone may include a plurality of pixels of the same size (hereinafter referred to as ‘central pixels’), and the peripheral pixel zone may include a plurality of pixels of the same size (hereinafter referred to as ‘peripheral pixels’). In this case, the size of a central pixel may be smaller than the size of a peripheral pixel. Here, the size of each pixel may be the planar area (e.g. the area defined by the x-axis direction and the y-axis direction) of the pixel, may be the length (or the width) of the pixel in the horizontal direction (e.g. the y-axis direction), or may be the length of the pixel in the vertical direction (e.g. the x-axis direction).

Each of the central pixels or the peripheral pixels may be a unit pixel pattern PI, and the image sensor may be formed such that the unit pixel patterns PI are repeated. For example, unlike the illustration in FIG. 2, the unit pixel pattern PI may include a cyan color filter Cy, a magenta color filter Mg, and a yellow color filter Ye as array elements. Alternatively, as illustrated in FIG. 2, the unit pixel pattern PI may be a Bayer pattern including a red color filter R, a green color filter G, and a blue color filter B as array elements.

Depending on the embodiment, each of the red color filter R, the green color filter G, and the blue color filter B may include a photodiode, a photo-transistor, a photo-gate, a pinned photodiode (PPD), or combinations thereof.

However, the embodiment is not limited as to the specific array elements of the unit pixel pattern PI or the specific arrangement form of the array elements.

For example, referring to FIGS. 2 to 4, the first pixel zone Z1 includes pixels having a first size, the second pixel zone Z2 includes pixels having a second size, the third pixel zone Z3 includes pixels having a third size, and the fourth pixel zone Z4 includes pixels having a fourth size. In this case, the first pixel zone Z1 may fall within the central pixel zone, and the fourth pixel zone Z4 may fall within the peripheral pixel zone. Accordingly, the first size of the pixel included in the first pixel zone Z1, which falls within the central pixel zone, may be smaller than the fourth size of the pixel included in the fourth pixel zone Z4, which falls within the peripheral pixel zone.

Alternatively, when the second pixel zone Z2 falls within the central pixel zone and the third pixel zone Z3 falls within the peripheral pixel zone, the second size of the pixel included in the second pixel zone Z2, which falls within the central pixel zone, may be smaller than the third size of the pixel included in the third pixel zone Z3, which falls within the peripheral pixel zone.

Alternatively, when both the second and third pixel zones Z2 and Z3 fall within the central pixel zone, the first, second, or third size of the pixel included in the first to third pixel zones Z1 to Z3, which fall within the central pixel zone, may be smaller than the fourth size of the pixel falling within the peripheral pixel zone.

Alternatively, when both the second and third pixel zones Z2 and Z3 fall within the peripheral pixel zone, the first size of the pixel included in the first pixel zone Z1, which falls within the central pixel zone, may be smaller than the second, third, or fourth size of the pixel falling within the peripheral pixel zone.

Further, the plurality of pixel zones included in the image sensors 100A to 100D according to the embodiments may be distinguished from each other in a direction from the center C of the image sensors 100A to 100D toward the edges E1 and E2 thereof, i.e. in a direction away from the center C thereof.

Further, the sizes of the plurality of pixels included in each of the plurality of pixel zones may be the same. That is, the sizes of the plurality of pixels disposed in the first pixel zone Z1 may be the same, the sizes of the plurality of pixels disposed in the second pixel zone Z2 may be the same, the sizes of the plurality of pixels disposed in the third pixel zone Z may be the same, and the sizes of the plurality of pixels disposed in the fourth pixel zone Z4 may be the same.

In this case, the sizes of the pixels included in the plurality of pixel zones may gradually increase in pixel zone units from the center C toward the edges E1 and E2. For example, as illustrated in FIGS. 2 to 4, when the image sensors 100A to 100C include the first to fourth pixel zones Z1 to Z4, the sizes of the pixels included in the first to fourth pixel zones Z1 to Z4 may gradually increase from the center C toward the edges E1 and E2. That is, the first size of each of the plurality of pixels included in the first pixel zone Z1, which is the closest to the center C, may be smaller than any of the second, third, and fourth sizes.

Further, the second size of the pixel included in the second pixel zone Z2, which is disposed closer to the center C, may be smaller than the third size of the pixel included in the third pixel zone Z3.

Further, among the third and fourth pixel zones Z3 and Z4, the third size of the pixel included in the third pixel zone Z3, which is disposed closer to the center C, may be smaller than the fourth size of the pixel included in the fourth pixel zone Z4.

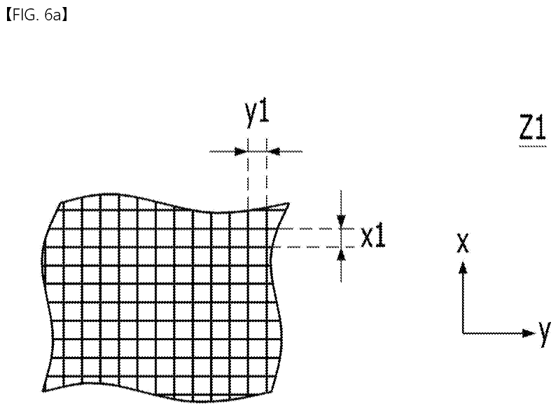

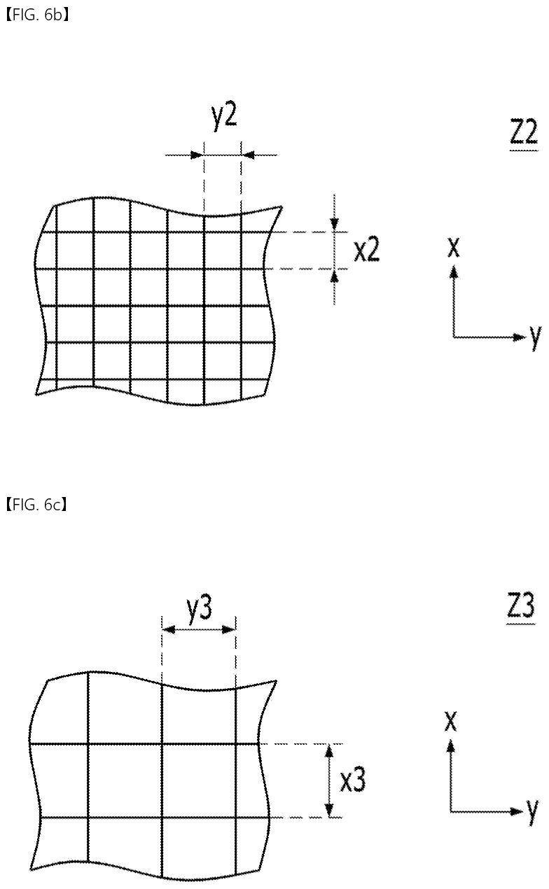

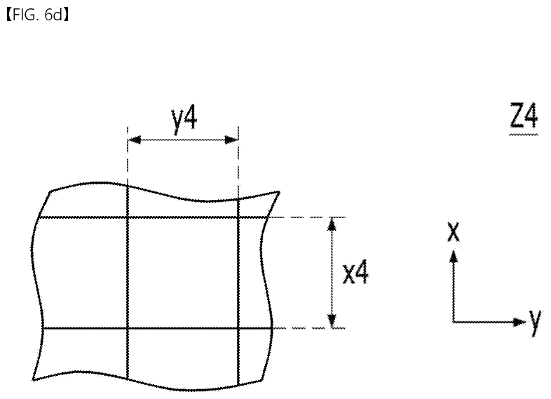

Hereinafter, the sizes of the pixels included in the image sensors 100A to 100C according to the embodiments illustrated in FIGS. 2 to 4 will be described with reference to FIGS. 6A to 6D. However, the description below may also be applied to the pixels included in the image sensor 100D illustrated in FIG. 5.

FIGS. 6A to 6D illustrate plan views of the respective first to fourth pixel zones Z1 to Z4 included in the image sensors 100A to 100C illustrated in FIGS. 2 to 4.

As illustrated in FIG. 6A, the plurality of pixels included in the first pixel zone Z1 have the same first size Δ1. Here, the first size Δ1 may be the planar area of each of the plurality of pixels included in the first pixel zone Z1, and may be expressed using Equation 1 below.

A1=x1·y1 [Equation 1]

Here, x1 and y1 may be the same as or different from each other.

Referring to FIG. 6B, the plurality of pixels included in the second pixel zone Z2 have the same second size A2. Here, the second size A2 may be the planar area of each of the plurality of pixels included in the second pixel zone Z2, and may be expressed using Equation 2 below.

A2=x2·y2 [Equation 2]

Here, x2 and y2 may be the same as or different from each other.

Referring to FIG. 6C, the plurality of pixels included in the third pixel zone Z3 have the same third size A3. Here, the third size A3 may be the planar area of each of the plurality of pixels included in the third pixel zone Z3, and may be expressed using Equation 3 below.

A3=x3·y3 [Equation 3]

Here, x3 and y3 may be the same as or different from each other.

Referring to FIG. 6D, the plurality of pixels included in the fourth pixel zone Z4 have the same fourth size A4. Here, the fourth size A4 may be the planar area of each of the plurality of pixels included in the fourth pixel zone Z4, and may be expressed using Equation 4 below.

A4=x4·y4 [Equation 4]

Here, x4 and y4 may be the same as or different from each other.

The relationships between the sizes A1 to A4 of the first to fourth zones expressed using Equations 1 to 4 above may be expressed using Equation 5 below.

A4>A3>A2>A1 [Equation 5]

For example, the first to fourth sizes A1 to A4 may have a relationship of multiples of 2 therebetween. However, the embodiment is not limited thereto. That is, with regard to the sizes of the pixels, A2 may be two times as large as A1, A3 may be two times as large as A2, and A4 may be two times as large as A3. For example, when x1 and y1 are the same, x2 and y2 are the same, x3 and y3 are the same, and x4 and y4 are the same, if x1 (or y1) is 0.5 μm, x2 (or y2) may be 1 μm, x3 (or y3) may be 2 μm, and x4 (or y4) may be 4 μm.

In general, according to the structure of the eye, i.e. the characteristics of human vision, when viewing an object, a human may feel a difference in resolution between the central portion of the object and the peripheral portion of the object. This is because cone cells are concentrated in the central area of the eye, and rod cells are concentrated in the peripheral area of the eye. For this reason, when viewing an object, a human recognizes the central portion of the object with a precise and high resolution, and recognizes the peripheral portion of the object with a resolution lower than that of the central portion of the object. Therefore, in the image sensors 100A to 100C according to the embodiments, when viewed in plan, the central pixels, which are located closer to the center C, have a smaller size, and the peripheral pixels, which are located farther away from the center C and closer to the edges E1 and E2, have a larger size than the central pixels so as to be suitable for the characteristics of human vision. Accordingly, the resolution gradually increases from the edges E1 and E2 of the image sensors 100A to 100C toward the center C thereof, thereby providing a high resolution (i.e. an effective resolution) capable of satisfying the characteristics of human vision.

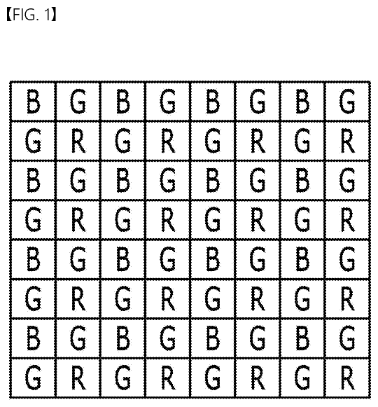

As a result, the image sensors 100A to 100D according to the embodiments are capable of providing an image having a higher resolution than that provided by the conventional image sensor illustrated in FIG. 1. Further, the resolution perceived by a human when all pixels included in the image sensor have the first size illustrated in FIG. 6A is similar to the resolution perceived by a human when only the central pixels, among the pixels included in the image sensor according to the embodiment, have the first size illustrated in FIG. 6A. Thus, not all pixels need to have the first size.

Further, the greater the number of pixels close to the center C are included in the central pixel zone, the greater the above-described effect obtained by reducing the size of the pixels close to the center C becomes. For example, in the case of the image sensor 100D illustrated in FIG. 5, the central pixel zone has a planar shape in which the central portion thereof is sharper than the peripheral portion thereof in order for a greater number of pixels close to the center C to be included in the central pixel zone. Therefore, the effective resolution of the image sensor 100D illustrated in FIG. 5 may be higher than that of the image sensor 100A illustrated in FIG. 2.

Further, when the aforementioned i (or j) is less than 3, the effect of improving the effective resolution may be slight, and when i (or j) is greater than 7, the structure of the image sensor may become complicated, and the overall luminance of the image sensor may be reduced. Therefore, i (or j) may be 3 to 7, for example, 5. However, the embodiment is not limited thereto.

In general, in the case of the conventional image sensor illustrated in FIG. 1, a first luminance level L1 of the central pixels located in the center of the image sensor is higher than a second luminance level L2 of the peripheral pixels located around the center of the image sensor. For example, the second luminance level L2 is only about 30% of the first luminance level L1. As such, in the conventional image sensor, the difference Δ1 between the first luminance level and the second luminance level is very large. In order to solve this, a process of reducing the first luminance level of the central pixels is required.

In contrast, in the case of the image sensors 100A to 100D according to the embodiments, since the size of the central pixels is smaller than the size of the peripheral pixels, the difference ΔL between the first luminance level L1 of the central pixels and the second luminance level L2 of the peripheral pixels is smaller than the difference Δ1 between the luminance levels in the conventional image sensor, as expressed using Equation 6 below.

ΔL=|L1−L2|<Δ1 [Equation 6]

For example, the second luminance level L2 may be 80% or more of the first luminance level L1.

Further, in the image sensors 100A to 100D according to the embodiments, the aforementioned first point, on the basis of which the central pixel zone and the peripheral pixel zone are distinguished from each other, may be determined as the point at which the second luminance level L2 is 80% or more of the first luminance level L1.

Therefore, in the case of the image sensors 100A to 100D according to the embodiments, a process of reducing the first luminance level of the central pixels is not required, thereby simplifying the structure and reducing manufacturing costs compared with the conventional art.

Further, like the embodiment, in the case in which the image sensors 100A to 100D are sectioned into a plurality of pixel zones when viewed in plan, the boundary BO between the plurality of pixel zones may be prominent due to the difference in the luminance level between the plurality of pixel zones.

In order to prevent this, according to an embodiment, an interpolation process may be performed such that the luminance level of the pixels located at the boundary between the central pixel zone and the peripheral pixel zone is adjusted so as to have an intermediate value of the first luminance level of the central pixels and the second luminance level of the peripheral pixels.

Alternatively, according to another embodiment, an interpolation process may be performed such that the luminance level of the pixels located at the boundary between the central pixel zone and the peripheral pixel zone is adjusted so as to have the average value of the first luminance level of the central pixels and the second luminance level of the peripheral pixels.

For example, referring to FIG. 2, assuming that the third pixel zone Z3 falls within the central pixel zone and the fourth pixel zone Z4 falls within the peripheral pixel zone, the luminance levels of the central pixels P31 to P36 and the peripheral pixels P41 to P46, which are located at the boundary BO between the zones Z3 and Z3, may be adjusted so as to have an average value or an intermediate value of the first luminance level of the central pixels P31 to P36 and the second luminance level of the peripheral pixels P41 to P46. The interpolation process described above may also be performed on the boundary between the first pixel zone Z1 and the second pixel zone Z2 or the boundary between the second pixel zone Z2 and the third pixel zone Z3.

As described above, in the image sensors 100A to 100D according to the embodiments, the luminance levels of pixels located at the boundary BO between the plurality of pixel zones are interpolated, thereby preventing the boundary BO between the plurality of pixel zones from becoming prominent, and thus providing natural images.

The image sensors according to the embodiments described above may be applied to various fields, and the embodiments are not limited as to the specific field of application of the image sensors. For example, the image sensors according to the embodiments may be applied to a mobile phone, a smartphone, a personal digital assistant (PDA), a portable multimedia player (PMP), a digital camera, a personal computer (PC), a server computer, a workstation, a laptop, a digital television (digital TV), a set-top box, a music player, a portable game console, a navigation system, etc.

Further, the image sensors according to the embodiments may be implemented in any of various packages. For example, at least some elements of an image sensor may be mounted using a package such as package-on-package (PoP), ball grid array (BGA), chip-scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flatpack (TQFP), small outline (SOIC), shrink small-outline package (SSOP), thin small outline (TSOP), thin quad flatpack (TQFP), system-in-package (SIP), multi-chip package (MCP), wafer-level fabricated package (WFP), or wafer-level processed stack package (WSP).

It will be apparent to those skilled in the art that various changes in form and details may be made without departing from the spirit and essential characteristics of the disclosure set forth herein. Accordingly, the above detailed description is not intended to be construed to limit the disclosure in all aspects and is to be considered by way of example. The scope of the disclosure should be determined by reasonable interpretation of the appended claims, and all equivalent modifications made without departing from the disclosure should be included in the following claims.

### MODE FOR INVENTION

Various embodiments have been described in the best mode for carrying out the disclosure.

### INDUSTRIAL APPLICABILITY

An image sensor according to embodiments may be used in a mobile phone, a smartphone, a personal digital assistant (PDA), a portable multimedia player (PMP), a digital camera, a personal computer (PC), a server computer, a workstation, a laptop, a digital television (digital TV), a set-top box, a music player, a portable game console, a navigation system, etc.

1. An image sensor, comprising:
a plurality of pixel zones disposed adjacent to each other,
wherein the plurality of pixel zones comprise:
a central pixel zone; and
a peripheral pixel zone disposed around the central pixel zone,
wherein the central pixel zone comprises a plurality of central pixels,
wherein the peripheral pixel zone comprises a plurality of peripheral pixels,
wherein sizes of the central pixels are smaller than sizes of the peripheral pixels,
wherein, when viewed in plan, the central pixel zone is a zone from a center of the image sensor to a first point, and
wherein the first point is a point falling within 3/10 to 7/10 of a total distance from the center to an edge of the image sensor.

2. (canceled)

3. The image sensor according to claim 1, wherein each of the central pixel zone and the peripheral pixel zone has a concentric circular planar shape.

4. The image sensor according to claim 1, wherein the peripheral pixel zone has a shape of a plane surrounding the central pixel zone.

5. The image sensor according to claim 1, wherein the peripheral pixel zone and the central pixel zone have different planar shapes from each other.

6. The image sensor according to claim 1, wherein a difference between a first luminance level of the central pixels and a second luminance level of the peripheral pixels is as follows:
ΔL=|L1−L2|<Δ1
where L1 represents the first luminance level, L2 represents the second luminance level, ΔL represents a luminance level difference between L1 and L2, and Δ1 represents a difference between the first luminance level and the second luminance level when sizes of the central pixels and sizes of the peripheral pixels are identical.

7. The image sensor according to claim 1, wherein a luminance level of pixels located at a boundary between the central pixel zone and the peripheral pixel zone has an intermediate value of a first luminance level of the central pixels and a second luminance level of the peripheral pixels.

8. The image sensor according to claim 1, wherein, when viewed in plan, the central pixel zone is determined as a point at which a second luminance level of the peripheral pixels is 80% or more of a first luminance level of the central pixels.

9. The image sensor according to claim 1, wherein the plurality of pixel zones comprise:
a first pixel zone comprising pixels having a first size, the first pixel zone falling within the central pixel zone;
a second pixel zone comprising pixels having a second size larger than the first size, the second pixel zone having a shape of a plane surrounding the first pixel zone;
a third pixel zone comprising pixels having a third size larger than the second size, the third pixel zone having a shape of a plane surrounding the second pixel zone; and
a fourth pixel zone comprising pixels having a fourth size larger than the third size, the fourth pixel zone having a shape of a plane surrounding the third pixel zone and falling within the peripheral pixel zone, and
wherein at least one of the second pixel zone or the third pixel zone falls within the central pixel zone or the peripheral pixel zone.

10. An image sensor, comprising:
a plurality of pixel zones disposed so as to be adjacent to each other and to be distinguished from each other in a direction from a center to an edge of the image sensor,
wherein each of the plurality of pixel zones comprises a plurality of pixels,
wherein sizes of pixels included in the plurality of pixel zones gradually increase from the center to the edge,
wherein the plurality of pixel zones include a central pixel zone, the central pixel zone including the center of the image sensor when viewed in plan, and
wherein the central pixel zone includes greater number of pixels located in the center of the image sensor than a number of pixels located in the edge of the image sensor.

11. The image sensor according to claim 10, wherein the plurality of pixel zones include:
a first pixel zone including pixels having a first size;
a second pixel zone including pixels having a second size larger than the first size, the second pixel zone having a shape of a plane surrounding the first pixel zone;
a third pixel zone including pixels having a third size larger than the second size, the third pixel zone having a shape of a plane surrounding the second pixel zone; and
a fourth pixel zone including pixels having a fourth size larger than the third size, the fourth pixel zone having a shape of a plane surrounding the third pixel zone.

12. The image sensor according to claim 11, wherein the central pixel zone includes the first pixel zone.

13. The image sensor according to claim 12, wherein the central pixel zone includes at least one of the second or third pixel zone.

14. The image sensor according to claim 10, wherein the size of each of the plurality of pixels corresponds to a planar area of the pixel.

15. The image sensor according to claim 10, wherein the size of each of the plurality of pixels corresponds to a length of the pixel in a horizontal direction.

16. The image sensor according to claim 10, wherein the size of each of the plurality of pixels corresponds to a length of the pixel in a vertical direction.

17. The image sensor according to claim 1, wherein each of the central pixel zone and the peripheral pixel zone has a polygonal planar shape.

18. The image sensor according to claim 1, wherein a luminance level of pixels located at a boundary between the central pixel zone and the peripheral pixel zone has an average value of a first luminance level of the central pixels and a second luminance level of the peripheral pixels.

19. The image sensor according to claim 1, wherein, among the plurality of pixels included in the central pixel zone, a number of pixels located in each of a horizontal axis and a vertical axis which pass the center when viewed in plan is greater than a number of pixels located between the horizontal axis and the vertical axis.

20. The image sensor according to claim 1, wherein the central pixel zone has a planar shape in which a central portion thereof is sharper than a peripheral portion thereof.

21. The image sensor according to claim 9, wherein the first to fourth sizes have a relationship of multiples of 2 therebetween.
